(19) United States
(12) Patent Application Publication
(10) Pub. No.: US 2017/0331041 A1
(43) Pub. Date: Nov. 16, 2017

(54) METHOD FOR MANUFACTURING ORGANIC ELECTRO-LUMINESCENT ELEMENT AND THE ORGANIC ELECTRO-LUMINESCENT ELEMENT

(71) Applicant: JOLED INC., Tokyo (JP)

(72) Inventor: Tomomi HIRAOKA, Tokyo (JP)

(73) Assignee: JOLED INC., Tokyo (JP)

(21) Appl. No.: 15/527,491

(22) PCT Filed: Nov. 11, 2015
(86) PCT No.: PCT/JP2015/005634

§ 371 Date: May 17, 2017

(30) Foreign Application Priority Data
Nov. 17, 2014 (JP) 2014-232871

(51) Int. Cl. H01L 51/00; H01L 33/42; H04N 5/40; H04N 7/015; B23K 26/351; C01B 13/14

(52) U.S. Cl. CPC H01L 51/0034; H01L 33/42; H04N 5/40; B23K 26/351; C08L 2203/20; C01B 13/14; H04N 7/015

(57) ABSTRACT

A method for manufacturing an organic electro-luminescent (EL) element includes: a first process of preparing an organic EL element which includes a positive electrode, an organic layer which includes a light-emitting layer, and a negative electrode, the organic EL element having a short-circuited portion where the positive electrode and the negative electrode are short-circuited; and a second process of emitting femtosecond laser light to at least one of: the transparent electrically conductive material layer and the metal layer in a short-circuited portion; and the transparent electrically conductive material layer and the metal layer around the short-circuited portion to bring the transparent electrically conductive material layer and the metal layer into high-resistance states.

### TECHNICAL FIELD

The present invention relates to a method for manufacturing an organic electro-luminescent element and the organic electro-luminescent element.

### BACKGROUND ART

Conventionally, there is a repair (resolve) scheme (e.g., see PTL 1 to PTL 4), which is carried out during a manufacturing process of an organic electro-luminescent (hereinafter, referred to as an organic EL) element which includes an organic layer between an anode (positive electrode) and a cathode (negative electrode), to repair a short circuit between the positive electrode and the negative electrode that is due to an electrically conductive foreign substance adhered to or trapped in the organic EL element, so that the short circuit does not affect the operation of the element.

The technologies disclosed in PTL 1 to 4 resolve such a short circuit by emitting laser light to or around a short-circuited portion.

### CITATION LIST

### Patent Literature

[PTL 1] Japanese Unexamined Patent Application Publication No. 2004-227852
[PTL 2] Japanese Unexamined Patent Application Publication No. 2003-178871
[PTL 3] Japanese Unexamined Patent Application Publication No. 2005-276600
[PTL 4] Japanese Unexamined Patent Application Publication No. 2008-235177

### SUMMARY OF INVENTION

### Technical Problem

Meanwhile, in recent years, organic EL elements which have configurations for achieving enhancement of cavity are manufactured as well. A positive electrode and a negative electrode may be short-circuited also in an organic EL element having such a configuration during the manufacturing process. Hence, the short circuit occurred in the organic EL element needs to be resolved.

Thus, in view of the above problems, an object of the present invention is to provide a method for manufacturing an organic EL element having a configuration for achieving enhancement of cavity, which reliably resolves a short circuit between a positive electrode and a negative electrode in the organic EL element.

### Solution to Problem

In order to solve the above problems, a method for manufacturing an organic electro-luminescent element according to one aspect of the present invention includes: a first process of preparing an organic EL element which includes a lower electrode, an organic layer which includes a light-emitting layer, and an upper electrode, at least one of the lower electrode and the upper electrode including a transparent electrically conductive material layer and a metal layer having an index of refraction higher than the transparent electrically conductive material layer, the organic EL element having a short-circuited portion where the lower electrode and the upper electrode are short-circuited; and a second process of emitting femtosecond laser light to at least one of: the transparent electrically conductive material layer and the metal layer in the short-circuited portion where the lower electrode and the upper electrode are short-circuited; and the transparent electrically conductive material layer and the metal layer around the short-circuited portion, to change a structure of the transparent electrically conductive material layer and a structure of the metal layer and bring the transparent electrically conductive material layer and the metal layer into high-resistance states.

### Advantageous Effects of Invention

According to the method of the present invention, a short circuit between the upper electrode and the lower electrode in an organic EL element which has a configuration for achieving enhancement of cavity is reliably resolved.

### BRIEF DESCRIPTION OF DRAWINGS

FIG. 1 is a cross-sectional schematic view of a short-circuited organic EL element.

FIG. 2 is a flowchart illustrating processes included in a method for manufacturing an organic EL element according to the present invention.

FIG. 3A is a top view of the organic EL element, for indicating an irradiation position of laser light.

FIG. 3B is a top view of the organic EL element, for indicating the irradiation position of the laser light.

FIG. 4 is a cross-sectional schematic view illustrating a process of resolving a short circuit in the organic EL element.

FIG. 5 is a cross-sectional schematic view of the organic EL element according to Embodiment 1 of the present invention.

FIG. 6 is a top view of an organic EL element, for indicating an irradiation position of laser light.

FIG. 7 is a cross-sectional schematic view illustrating a process of resolving a short circuit in the organic EL element.

FIG. 8 is a cross-sectional schematic view of the organic EL element according to Embodiment 2 of the present invention.

FIG. 9 is a cross-sectional schematic view illustrating a process of resolving a short circuit in the organic EL element according to Embodiment 2.

FIG. 10 is a cross-sectional schematic view illustrating a process of resolving a short circuit in an organic EL element according to Embodiment 3 of the present invention.

FIG. 11 is a cross-sectional schematic view of the organic EL element according to Embodiment 3.

FIG. 12 is an external view of a television system which includes the organic EL element according to the present invention.

### DESCRIPTION OF EMBODIMENTS

A method for manufacturing an organic electro-luminescent element according to the present invention includes: a first process of preparing an organic EL element which includes a lower electrode, an organic layer which includes a light-emitting layer, and an upper electrode, at least one of the lower electrode and the upper electrode including a transparent electrically conductive material layer and a metal layer having an index of refraction higher than the transparent electrically conductive material layer, the organic EL element having a short-circuited portion where the lower electrode and the upper electrode are short-circuited; and a second process of emitting femtosecond laser light to at least one of: the transparent electrically conductive material layer and the metal layer in the short-circuited portion where the lower electrode and the upper electrode are short-circuited; and the transparent electrically conductive material layer and the metal layer around the short-circuited portion, to change a structure of the transparent electrically conductive material layer and a structure of the metal layer and bring the transparent electrically conductive material layer and the metal layer into high-resistance states.

According to this aspect, the light emitted by the organic EL element is refracted by the metal layer so as to condense. Thus, enhancement of cavity of the organic EL element is achieved. Moreover, the laser light is emitted to the ITO layer and the metal layer to bring the ITO layer and the metal layer into high-resistance states, thereby reliably resolving a short circuit between the lower electrode and the upper electrode.

Moreover, the metal layer may include silver.

According to this aspect, an organic EL element having a short circuit resolved and having an enhanced cavity configuration is manufactured.

Moreover, the metal layer may include magnesium.

According to this aspect, an organic EL element having a short circuit resolved and having an enhanced cavity configuration is manufactured.

Moreover, the transparent electrically conductive material layer may include a transparent metal oxide.

According to this aspect, since a component of the electrode is the transparent metal oxide, the electrode can be brought into the high-resistance state by changing its structure more reliably by emitting femtosecond laser light to the electrode.

Moreover, the organic layer in the short-circuited portion may contain an electrically conductive foreign substance.

According to this aspect, the short circuit between the lower electrode and the upper electrode can be resolved even in the following situations: the lower electrode and the upper electrode are short-circuited due to the electrically conductive foreign substance, that is, the lower electrode and the upper electrode are in direct contact with each other due to the electrically conductive foreign substance; and the lower electrode and the upper electrode are prone to passing current therethrough due to the fact that a distance between the electrically conductive foreign substance and the lower electrode and a distance between the electrically conductive foreign substance and the upper electrode are short.

Moreover, the method may further include detecting the electrically conductive foreign substance, wherein the femtosecond laser light is emitted to the transparent electrically conductive material layer and the metal layer in a region around the electrically conductive foreign substance.

As the laser light is emitted to the foreign substance, the foreign substance absorbs energy of the laser light and oscillates. This may damage a pixel in which the organic EL element is included. According to this aspect, however, the position of the foreign substance is detected and the laser light is emitted around the foreign substance, thereby resolving a short circuit without damaging the pixel.

Moreover, the organic layer may be thinner in the short-circuited portion than in portions other than the short-circuited portion.

According to this aspect, a short circuit between the lower electrode and the upper electrode due to the following situations can be resolved: a pinhole is formed during the course of forming the organic EL element and thus the lower electrode and the upper electrode are directly in contact with each other; and the organic layer is thin and thus the lower electrode and the upper electrode are close to each other and each prone to passing current therethrough.

Moreover, the organic electro-luminescent element according to the present invention may include: a lower electrode; an organic layer which includes a light-emitting layer; and an upper electrode, wherein at least one of the lower electrode and the upper electrode includes a transparent electrically conductive material layer and a metal layer having an index of refraction higher than the transparent electrically conductive material layer, and a portion of the transparent electrically conductive material layer and a portion of the metal layer have been changed in structure by laser radiation and are in high-resistance states.

According to this aspect, the light emitted by the organic EL element is refracted by the metal layer so as to condense. Thus, enhancement of cavity of the organic EL element is achieved. Moreover, the laser light is emitted to the ITO layer and the metal layer to bring the ITO layer and the metal layer into high-resistance states, thereby reliably resolving a short circuit between the lower electrode and the upper electrode.

Moreover, the metal layer may include silver.

According to this aspect, the organic EL element having the short circuit resolved and having an enhanced cavity configuration is provided.

Moreover, the metal layer may include magnesium.

According to this aspect, the organic EL element having the short circuit resolved and having an enhanced cavity configuration is provided.

Moreover, an electrically conductive foreign substance may be present proximate the portion of the transparent electrically conductive material layer and the portion of the metal layer.

According to this aspect, even though the organic EL element contains the electrically conductive foreign substance between the lower electrode and the upper electrode, the short circuit between the lower electrode and the upper electrode has been resolved. Thus, the organic EL element is usable.

Hereinafter, a method for manufacturing an organic EL element according to embodiments of the present invention is described, with reference to the accompanying drawings. Note that the same reference sign is used to refer to the same or like element throughout the drawings and duplicate description is omitted.

The following describes embodiments of the present invention in detail, with reference to the drawings. Note that the embodiments described below show specific examples of the present invention. Values, shapes, materials, components, and arrangement and connection between the components, steps, the order of the steps, etc. illustrated in the following embodiments are mere examples and not intended to limit the present invention. Moreover, among the components of the embodiments below, components not recited in any one of the independent claims defining the most generic part of the inventive concept of the present invention are described as arbitrary components of the embodiments.

### Embodiment 1

In the following, Embodiment 1 according to the present invention is described with reference to the accompanying drawings.

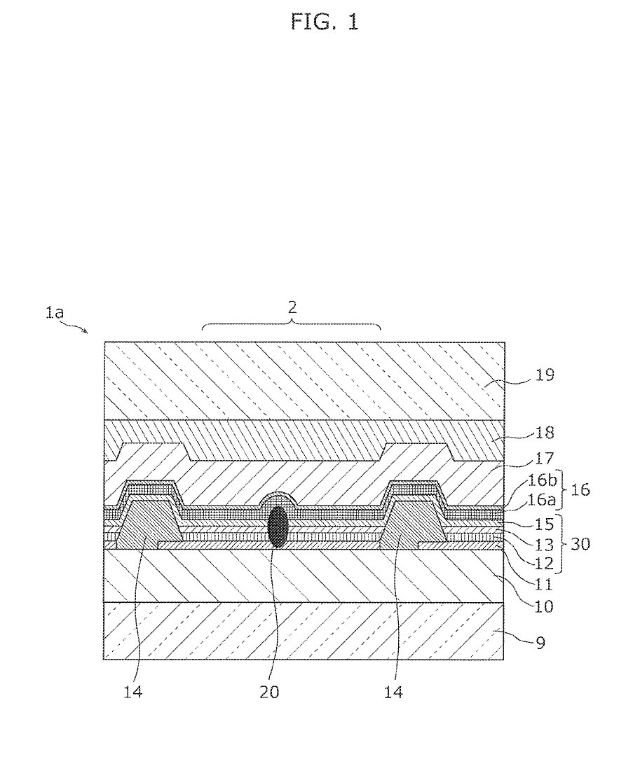

FIG. 1 is a cross-sectional schematic view illustrating a cross-sectional structure of a short-circuited organic EL element. An organic EL element 1a illustrated in the figure is an organic functional device which includes a positive electrode, a negative electrode, and an organic layer includes a light-emitting layer and is disposed between the positive electrode and the negative electrode.

As illustrated in FIG. 1, the organic EL element 1a includes, on a substrate 9, a planarizing film 10, a positive electrode 11, a hole-injection layer 12, a light-emitting layer 13, partitions 14, an electron-injection layer 15, a negative electrode 16, a thin-film sealing layer 17, a sealing resin layer 18, and a transparent glass 19.

Here, the positive electrode 11 and the negative electrode 16 correspond to a lower electrode and an upper electrode, respectively, according to the present invention. A combination of the hole-injection layer 12, the light-emitting layer 13, and the electron-injection layer 15 corresponds to an organic layer according to the present invention.

The substrate 9 is, for example, a substrate which includes a thin film transistor (TFT).

The planarizing film 10 includes, by way of example, an insulative organic material and is formed on a substrate which includes, for example, a drive thin-film transistor (TFT), etc.

The positive electrode 11 is an anode to which holes are supplied, that is, current flows in the positive electrode 11 from an external circuit. The positive electrode 11 is, for example, a reflecting electrode which includes, for example, Al or silver alloy APC (silver-palladium-copper alloy) and is layered on the planarizing film 10. The reflecting electrode has a thickness of, by way of example, 10 nm or more and 40 nm or less. Note that the positive electrode 11 may have a two-layer structure which includes, for example, indium tin oxide (ITO) and silver alloy APC or the like.

The hole-injection layer 12 includes a material having a hole-injection property, as a principal component. The material having a hole-injection property has capabilities of stably injecting holes, injected from the positive electrode 11, into the light-emitting layer 13. For example, a compound such as PEDOT (polyethylenedioxythiophene) or aniline is employed as the material.

The light-emitting layer 13 emits light in response to application of voltage between the positive electrode 11 and the negative electrode 16. The light-emitting layer 13 has a structure in which, for example, α-NPD (Bis [N-(1-naphthyl)-N-phenyl] benzidine) and Alq₃ (tris-(8-hydroxyquinoline) aluminum) are layered as the bottom layer and the top layer, respectively. The light-emitting layer 13 has a thickness of, by way of example, 20 nm or more and 70 nm or less.

The electron-injection layer 15 includes a material having an electron-injection property, as a principal component. The material having an electron-injection property has capabilities of stably injecting the electrons, injected from the negative electrode 16, into the light-emitting layer 13. For example, polyphenylenevinylene (PPV) is employed as the material.

The negative electrode 16 is a cathode to which electrons are supplied, that is, current flows out from the negative electrode 16 to an external circuit. The negative electrode 16 has a structure in which, for example, an ITO layer 16a, which is a transparent metal oxide, and a metal layer 16b are layered, as illustrated in FIG. 1. Note that the ITO layer 16a may include a material, such as Mg, Ag, and be formed as a transparent electrode. The metal layer 16b includes a material having an index of refraction higher than the ITO layer 16a. This causes light emitted by an organic EL element to be refracted so as to condense. Thus, enhancement of cavity of the organic EL element is achieved. The metal layer 16b may include a material such as silver (Ag), silver alloy APC, or magnesium (Mg), for example.

The ITO layer 16a has a thickness of, by way of example, 30 nm or more and 90 nm or less. The metal layer 16b has a thickness of, by way of example, 15 nm or more and 30 nm or less.

The partitions 14 are walls for separating the light-emitting layer 13 in light-emitting regions. The partitions 14 include photosensitive resins, for example.

The thin-film sealing layer 17 contains, for example, silicon nitride, and has capabilities of blocking vapor or oxygen from the light-emitting layer 13 and the negative electrode 16 described above. This is to prevent deterioration (oxidization) of the light-emitting layer 13 itself or the negative electrode 16 due to exposure to vapor or oxygen.

The sealing resin layer 18 is an acrylic or epoxy-based resin, and has capabilities of bonding the transparent glass 19 and the layer consisting of the components from the planarizing film 10 on the aforementioned substrate 9 to the thin-film sealing layer 17.

The transparent glass 19 is a substrate which protects a light-emitting surface of a light-emitting panel. The transparent glass 19 is, for example, a transparent alkali-free glass having a thickness of 0.5 mm.

The above described configurations of the positive electrode 11, the light-emitting layer 13, and the negative electrode 16 are basic configurations of the organic EL element. Owing to such configurations, holes and electrons, respectively from the negative electrode 16 and the positive electrode 11, are injected into the light-emitting layer 13 when appropriate voltage is applied between the positive electrode 11 and the negative electrode 16. These holes and electrons injected in the light-emitting layer 13 are recombined in the light-emitting layer 13 and generate energy. The light-emitting material included in the light-emitting layer 13 is excited by the energy and emits light.

Note that the materials comprising the hole-injection layer 12 and the electron-injection layer 15 are not limited to the present embodiment, and known organic materials or inorganic materials are employed.

Moreover, as a configuration of the organic EL element 1a, a hole-transport layer may be disposed between the hole-injection layer 12 and the light-emitting layer 13 or an electron-transport layer may be disposed between the electron-injection layer 15 and the light-emitting layer 13.

A hole-transport layer contains a material having a hole-transport property, as a principal component. The material having a hole-transport property is electron-donating, has propensities to become cations (holes) and convey holes to the light-emitting layer 13 by an intermolecular charge-transfer reaction, and is suitable for transport of charges from the positive electrode 11 to the light-emitting layer 13.

An electron-transport layer contains a material having an electron-transport property, as a principal component. The material having an electron-transport property is electron-accepting, has propensities to become anions and convey electrons to the light-emitting layer 13 by an intermolecular charge-transfer reaction, and is suitable for transport of charges from the negative electrode 16 to the light-emitting layer 13.

The organic EL element 1a may further have a configuration of including color filters on the bottom surface of the transparent glass 19 so as to cover the light-emitting regions separated by the partitions 14. The color filters are for adjusting colors red, green, and blue.

Note that in the present disclosure, a combination of the hole-injection layer 12, the light-emitting layer 13, and the electron-injection layer 15 is referred to as an organic layer 30. If the organic EL element 1a includes a hole-transport layer and an electron-transport layer, these layers are also included in the organic layer 30. The organic layer 30 has a thickness of, by way of example, 100 nm or more and 200 nm or less. Moreover, a combination of the planarizing film 10, the positive electrode 11, the organic layer 30, the negative electrode 16, the thin-film sealing layer 17, the sealing resin layer 18, and the transparent glass 19, which are disposed in each of the light-emitting regions separated by the partitions 14, is referred to as a pixel 2.

Further, in the organic EL element 1a illustrated in FIG. 1, an electrically conductive foreign substance 20 is trapped between the positive electrode 11 and the negative electrode 16 during the manufacturing process, and the positive electrode 11 and the negative electrode 16 are short-circuited via the foreign substance 20. In order to resolve the short circuit, structures of the ITO layer 16a and the metal layer 16b forming a portion 16c of the negative electrode 16 above a position where the foreign substance 20 is trapped, are changed by emitting laser light 125 to the portion 16c to bring the portion 16c into a high-resistance state, as described in detail below. This resolves (repairs) the short circuit between the positive electrode 11 and the negative electrode 16 caused by the foreign substance 20. The process of repairing the short-circuited portion is described below.

Next, a method for manufacturing the organic EL element 1a is described.

First, a process of forming the organic EL element 1a illustrated in FIG. 1 is described. Initially, the planarizing film 10 which includes the insulative organic material is formed on the substrate 9 which includes the TFT, after which the positive electrode 11 is formed on the planarizing film 10.

The positive electrode 11 is formed by, for example, depositing 30 nm of Al on the planarizing film 10 by a sputtering method and subjecting the planarizing film 10 having Al thereon to a patterning process by photolithography and wet etching.

The hole-injection layer 12 is formed by, for example, dissolving PEDOT into a solvent which includes xylene, and spin coating the PEDOT solvent on the positive electrode 11.

Next, the light-emitting layer 13 is formed by, for example, layering α-NPD and Alq₃ on the hole-injection layer 12 by a vacuum deposition method.

Next, the electron-injection layer 15 is formed by, for example, dissolving polyphenylenevinylene (PPV) into a solvent which includes, for example, xylene or chloroform, and spin coating the solvent on the light-emitting layer 13.

Next, the ITO layer 16a is formed on the electron-injection layer 15 without exposing the substrate having the electron-injection layer 15 formed thereon to the atmosphere. Specifically, 75 nm of ITO is layered on the electron-injection layer 15 by a sputtering method. At this time, the ITO layer 16a is in an amorphous state.

Next, the metal layer 16b is formed on the ITO layer 16a. Specifically, 20 nm of metal, for example, Ag, is layered on the ITO layer 16a by a sputtering method to form the metal layer 16b. The thicker the metal layer 16b is, the less the transmission of light emitted by the organic EL element through the metal layer 16b, resulting in a dark display on the organic EL panel. Moreover, the presence of the metal layer 16b reduces an angle of view of the organic EL panel. To be more specific, the presence of the metal layer 16b allows further enhancement of cavity of an organic EL display device.

The organic EL element 1a having capabilities as a light-emitting element is formed by the manufacturing process as described above. Note that the partitions 14 which include surface-photosensitive resins are formed at predetermined positions after the process of forming the positive electrode 11 and before the process of forming the hole-injection layer 12.

Next, the thin-film sealing layer 17 is formed on the metal layer 16b. Specifically, 500 nm of silicon nitride is layered on the metal layer 16b by, for example, a plasma CVD method. Since the thin-film sealing layer 17 is formed in contact with a surface of the metal layer 16b, preferably, requirements of the thin-film sealing layer 17, particularly, as a protective film, are strict. For example, a non-oxygen-based inorganic material, as represented by the silicon nitride discussed above, is a preferable material for the thin-film sealing layer 17. Alternatively, the thin-film sealing layer 17 may include, for example, an oxygen-based inorganic material, such as silicon oxide (SiₓO_{y}) and silicon oxynitride (SiₓO_{y}N_{z}), or may have a multi-layer structure of these inorganic materials. The method of forming the thin-film sealing layer 17 is not limited to the plasma CVD method, and may be any other method, such as a sputtering method using argon plasma.

Next, the sealing resin layer 18 is applied to a surface of the thin-film sealing layer 17. Then, the transparent glass 19 is disposed on the sealing resin layer 18 applied on the thin-film sealing layer 17. Here, in the case of manufacturing an organic EL element 1a in which color filters are disposed, the color filters are previously formed on a major surface of the transparent glass 19. Then, the transparent glass 19 is disposed on the sealing resin layer 18 applied on the thin-film sealing layer 17, with a surface down, the surface having the color filter formed thereon.

Last, the transparent glass 19 is pressurized vertically downward from the top surface side and heat or energy ray is applied to cure the sealing resin layer 18, thereby adhering the transparent glass 19 and the thin-film sealing layer 17 to the sealing resin layer 18.

The organic EL element 1a is formed by such a formation method.

Note that the processes of forming the positive electrode 11, the hole-injection layer 12, the light-emitting layer 13, the electron-injection layer 15, and the negative electrode 16 are not limited to the present embodiment.

Here, as illustrated in FIG. 1, the electrically conductive foreign substance 20 may be trapped between the positive electrode 11 and the negative electrode 16, and the positive electrode 11 and the negative electrode 16 may be short-circuited via the foreign substance 20 during the manufacturing process. For example, Al, which is a material of the positive electrode 11, adheres over the positive electrode 11 after the formation of the positive electrode 11 and, subsequently, the hole-injection layer 12, the light-emitting layer 13, the electron-injection layer 15, and the negative electrode 16 are layered on the positive electrode 11, thereby creating the foreign substance 20. The foreign substance 20 has, by way of example, a diameter of about 200 nm and a height of about 500 nm. Since the positive electrode 11 and the negative electrode 16 are short-circuited due to the foreign substance 20, the organic EL element 1a included in the pixel 2 ends up with an unlit pixel which emits no light.

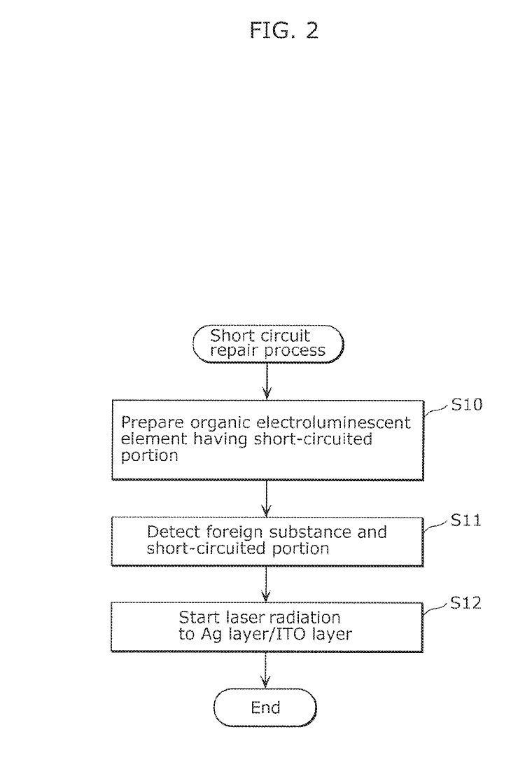

Next, the process of repairing a short-circuited portion in the organic EL element 1a is described, the short-circuited portion being where the positive electrode 11 and the negative electrode 16 are short-circuited due to the foreign substance 20 described above. FIG. 2 is a flowchart illustrating a process of resolving the short circuit in the organic EL element 1a.

The short-circuited portion is repaired by emitting the laser light to the negative electrode 16 via the transparent glass 19. Specifically, the organic EL element 1a having a short-circuited portion is prepared (step S10), the portion short-circuited due to the foreign substance 20 or the trapped foreign substance 20 itself is detected (step S11), and emission of the laser light from the transparent glass 19 side to the ITO layer 16a and the metal layer 16b which are included in the negative electrode 16 above the short-circuited portion in the pixel 2 is initiated (step S12). This changes the structure of the portion of the negative electrode 16 subjected to the laser radiation, bringing the portion of the negative electrode 16 into a high-resistance state, thereby resolving the short circuit between the positive electrode 11 and the negative electrode 16.

Note that step S10 corresponds to a first process according to the present invention and step S12 corresponds to a second process according to the present invention.

The foreign substance 20 or the short-circuited portion where the positive electrode 11 and the negative electrode 16 are short-circuited is detected by, for example, inputting to each pixel 2 a luminance signal voltage corresponding to an intermediate luminance level and detecting, by luminance measuring equipment or by visual inspection, a pixel which emits light having a low luminance as compared to an emission luminance of a normal pixel.

Note that the detection of the short-circuited portion or the foreign substance 20 is not limited to the above method. For example, values of current through the positive electrode 11 and the negative electrode 16 included in the organic EL element may be measured and the short-circuited portion or the foreign substance 20 may be detected based on magnitudes of the current values. In this case, a portion which yields a current value equivalent to a current value of a normal pixel when a forward bias voltage is applied and in which leakage light emission is observed when a reverse bias voltage is applied may be determined to be a short-circuited portion or a portion where the foreign substance 20 is trapped.

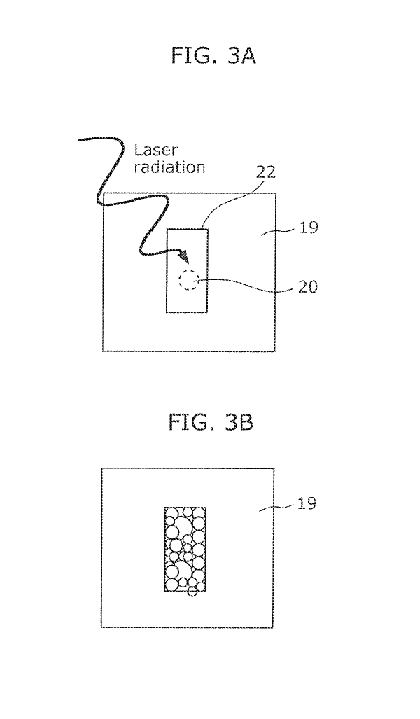

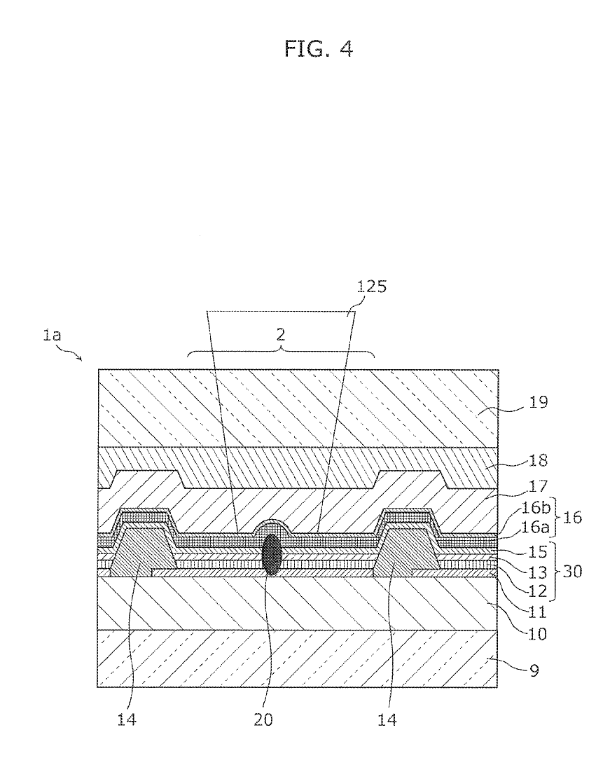

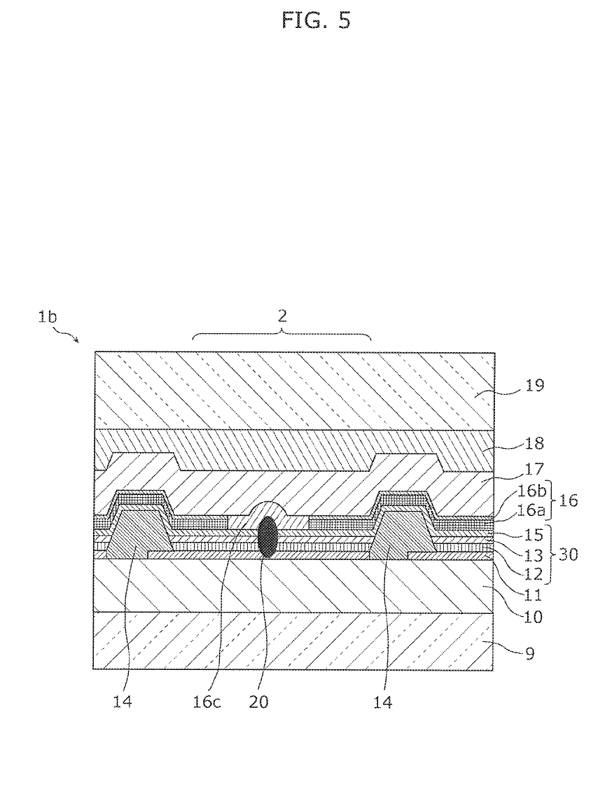

FIGS. 3A and 3B are top views of the organic EL element, for indicating an area in which the laser light is emitted to the foreign substance 20. FIG. 3A is a top view of the organic EL element 1a before being subjected to the laser light 125. FIG. 3B is a top view of an organic EL element 1b subjected to the laser light 125. In FIGS. 3A and 3B, a region 22 indicated by the box defined by the solid lines is an emission range of the laser light. FIGS. 4 and 5 are cross-sectional schematic views illustrating a process of resolving a short circuit in the organic EL element. FIG. 4 is a cross-sectional schematic view of the organic EL element 1a before being subjected to the laser light 125. FIG. 5 is a cross-sectional schematic view of the organic EL element 1b subjected to the laser light 125.

After the detection of the foreign substance 20, the laser light 125 is emitted to the portion where the positive electrode 11 and the negative electrode 16 are short-circuited due to the foreign substance 20 and to the negative electrode 16 in the region 22 around the portion as illustrated in FIGS. 3A and 4. For example, the region 22 has a size of 5 μm×10 μm.

The type of the laser light 125 is, for example, femtosecond laser light whose output energy is 1 μJ or greater and 30 μJ or less and pulse width is a few hundred femtoseconds. The laser light has a wavelength of, by way of example, 900 nm or more and 2500 nm or less.

The focus of the laser light 125 is set at the negative electrode 16. Note that the focus of the laser light 125 is not limited to the negative electrode 16 only, and the laser light 125 may be emitted to the negative electrode 16 and the organic layer 30 or may be emitted to only one of the ITO layer 16a and the metal layer 16b that are included in the negative electrode 16.

After the emission of the laser light 125, the ITO layer 16a, which used to be in an amorphous state, in the region 22 in the organic EL element 1b, has been changed to have a granulated structure, as illustrated in FIGS. 3B and 5. Moreover, metal atoms comprising the metal layer 16b have been diffused from the metal layer 16b to the ITO layer 16a. Thus, the region 22 in the organic EL element 1b subjected to the laser light 125 is in a mixed state of the ITO layer 16a having the granulated structure and metal atoms comprising the metal layer 16b.

The granulated structure as used herein refers to a structure in which numerous particles are collected while leaving air gaps between the particles. The particles forming the granulated structure have diameters of, by way of example, 10 nm or greater and 500 nm or less. The particles may be in spherical shapes or may be in flaked shapes. In the portion 16c of the negative electrode 16 which has the granulated structure, the ITO layer 16a having the granulated structure and metal atoms comprising the metal layer 16b are mixed and air gaps are created between the particles. It is contemplated that due to the air gaps, the portion 16c of the negative electrode 16 which has the granulated structure is less likely to pass current therethrough and has a resistance state higher than a portion of the negative electrode 16 that does not have the granulated structure.

The portion of the negative electrode 16 that does not have the granulated structure has a resistance value (resistivity) of, by way of example, 50Ω. In contrast, a portion 16d of the negative electrode which has the granulated structure has a resistance value of, by way of example, 40 MΩ. As such, the negative electrode 16 in the region 22 is brought into a high-resistance state, and thereby the short circuit between the positive electrode 11 and the negative electrode 16 in the region 22 is resolved and light emission of the pixel 2 is recovered.

Note that if the laser light 125 is emitted to the negative electrode 16 and also to the organic layer 30, the region 22 in the organic EL element 1b subjected to the laser light 125 is in a mixed state of the ITO layer 16a having the granulated structure, metal atoms comprising the metal layer 16b, and, additionally, the organic material comprising the organic layer 30.

For example, if the laser light has a frequency of oscillation of 2 kHz, the maximum of laser light power may be 13 μW and the minimum of the laser light power may be 4 μW. The maximum of the laser light power is an upper limit for protecting from damage the organic layer 30 that is disposed below the negative electrode 16. The minimum of the laser light power is a lower limit of laser light power that is necessary to granulate the component of the negative electrode 16.

The maximum of the laser light power 13 μW is 7.5 nJ in terms of output energy of the laser light. The minimum of the laser light power 4 μW is 2 nJ in terms of output energy of the laser light.

Moreover, a difference (power margin) between the maximum and the minimum of the laser light power is great in a range of at least 400 fs to at most 800 fs of the pulse width of the laser light. Thus, the structure of the component of the negative electrode 16 can easily be granulated by emitting femtosecond laser light having the pulse width of this range to the organic EL element 1a.

Moreover, thermal energy of the laser light emitted to the region 22 may spread to an area around the region 22, for example, an area about 1 μm away from the position to which the laser light is emitted, which may granulate and bring the negative electrode 16 in the area into a high-resistance state. In this case also, a short circuit between the positive electrode 11 and the negative electrode 16 is resolved, recovering light emission of the pixel 2.

As described above, according to the method for manufacturing the organic EL element of the present embodiment, even if the organic EL element includes the negative electrode 16 that includes a ITO layer and a metal layer for the purpose of achieving the enhancement of cavity, a short circuit between the positive electrode and the negative electrode can be reliably resolved by emitting laser light to the ITO layer and the metal layer to bring the negative electrode 16 into a high-resistance state.

Note that the output energy of the laser light 125 is not limited to the aforementioned range and may be to an extent that permits the granulation of the negative electrode 16 without destroying the thin-film sealing layer 17.

Moreover, the direction from which the laser light 125 is emitted to the negative electrode 16 is not limited to the transparent glass 19 side. If the positive electrode includes a transparent electrically conductive material, the focus position of the laser light may be adjusted and the laser light may be emitted to the positive electrode 11 from the transparent glass 19 side. Moreover, not limiting to the transparent glass 19 side, the laser light may be emitted from the substrate 9 side. In this case, the substrate 9 may include a transparent glass.

### Embodiment 2

Next, Embodiment 2 of the present invention is described. The present embodiment is the same as Embodiment 1, except for an area of an organic EL element to which laser light is emitted.

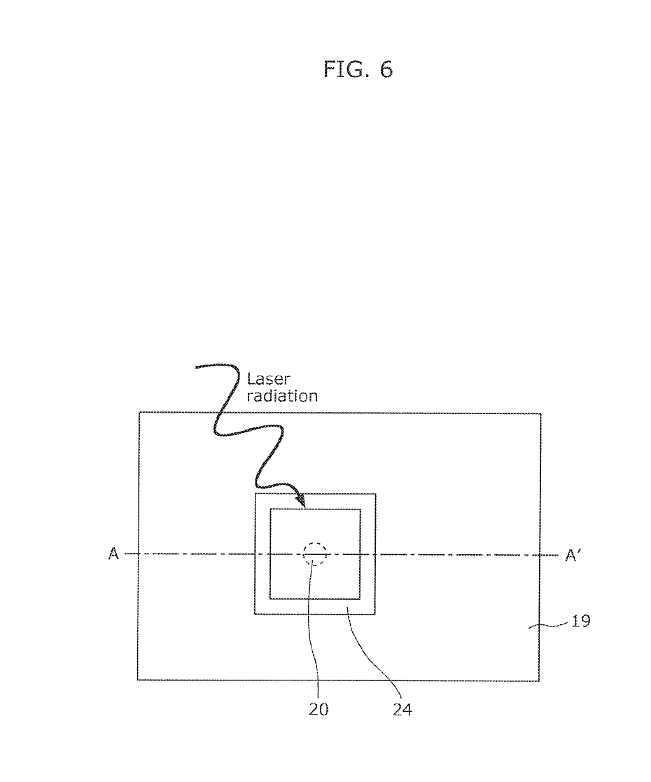

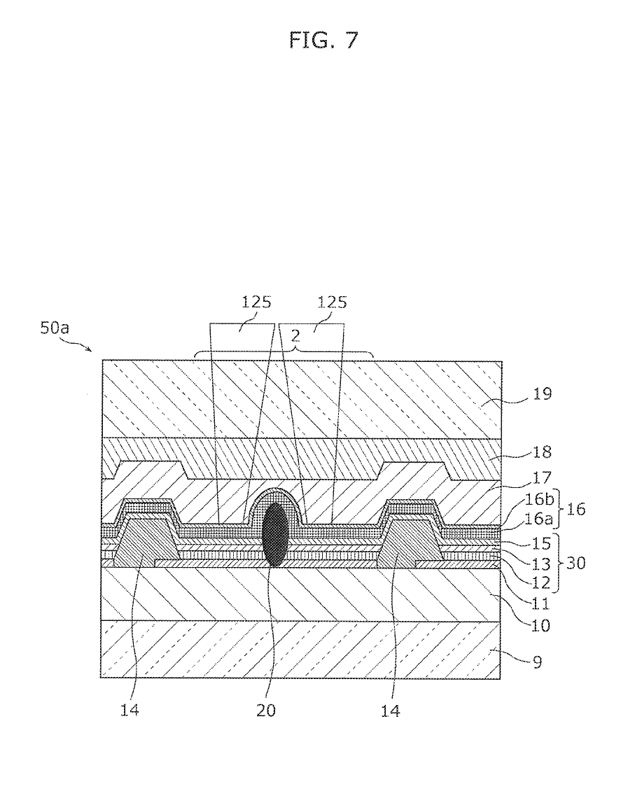

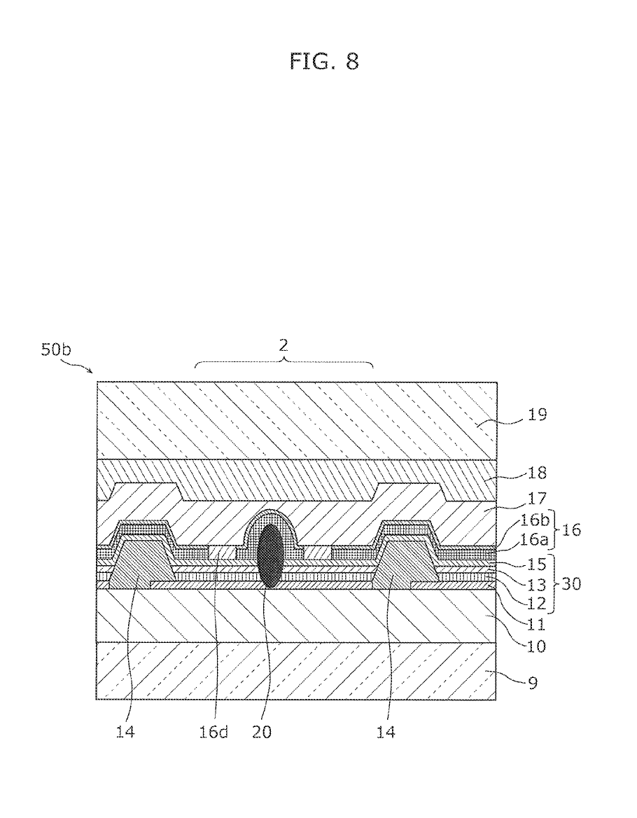

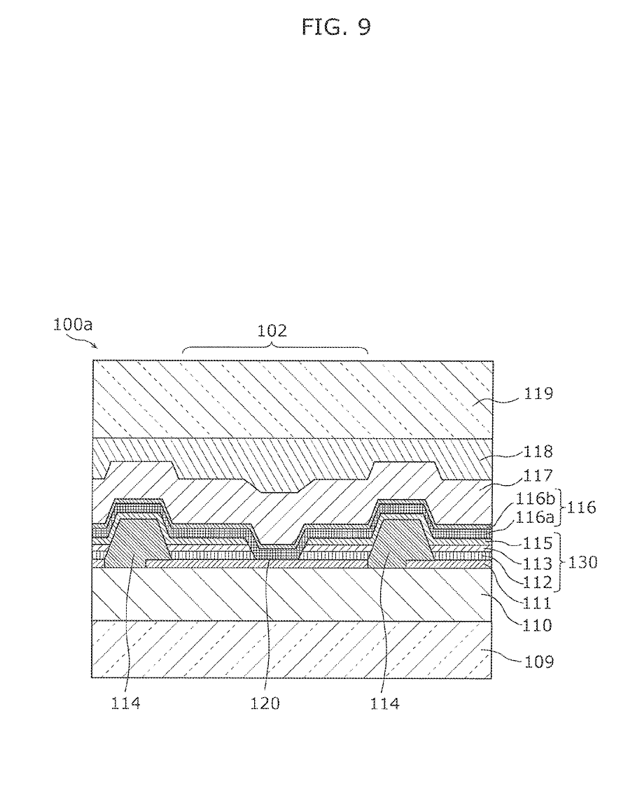

FIG. 6 is a top view of the organic EL element, for indicating an irradiation position of laser light. FIGS. 7 and 8 are cross-sectional schematic views illustrating a process of resolving a short circuit in the organic EL element. FIG. 7 is a cross-sectional schematic view of an organic EL element 50a before being subjected to laser light 125. FIG. 8 is a cross-sectional schematic view of an organic EL element 50b subjected to the laser light 125.

As illustrated in FIGS. 6 and 7, in the present embodiment, the laser light 125 is emitted to the negative electrode 16 in a predetermined region around a foreign substance 20. For example, the laser light is emitted in a 20 μm×20 μm square peripheral shape to the ITO layer 16a and the metal layer 16b in a region about 10 μm away from the foreign substance 20, as illustrated in FIG. 6. As the laser light 125 is emitted, the structure of the portion 16d of the negative electrode is granulated, thereby resolving the short circuit between the positive electrode 11 and the negative electrode 16, as illustrated in FIG. 8.

As illustrated in Embodiment 1, as the laser light 125 is emitted to the negative electrode 16 in a predetermined region where the foreign substance 20 is present, the foreign substance 20 may absorb the energy of the laser light 125, in response to which the foreign substance 20 may oscillate and damage the pixel 2. Moreover, if the foreign substance 20 is large in size, the power of the laser light 125 needs to be increased or emission period of the laser light 125 needs to be extended. Thus, the organic layer 30 may be damaged by heat generated by the laser light 125.

On the other hand, according to the method illustrated in the present embodiment, since the focus of the laser light 125 is set at the negative electrode 16 in the region around the foreign substance 20, absorption of the energy of the laser light 125 into the foreign substance 20 can be inhibited. Thus, the structure of the negative electrode 16 in the region around the foreign substance 20 can be granulated, without damaging the pixel 2 and the organic layer 30.

As described above, according to the method of the present embodiment, in the organic EL element 50b subjected to the laser light 125, the negative electrode 16 in the area around the foreign substance 20 is granulated, bringing the negative electrode 16 into a high-resistance state. This resolves the short circuit between the positive electrode 11 and the negative electrode 16 and recovers light emission of the pixel 2.

Note that as with Embodiment 1 described above, the type, wavelength, and output energy of the laser light 125 may be changed in any way, insofar as the ITO layer 16a and the metal layer 16b can be brought into high-resistance states and the thin-film sealing layer 17 is not destroyed. Moreover, as with Embodiment 1, the process of detecting a position of the foreign substance 20 may be provided prior to the repair process.

### Embodiment 3

Next, Embodiment 3 according to the present invention is described. The present embodiment is the same as Embodiment 1, except that the present embodiment repairs a short-circuited portion of an organic EL element which is caused due to direct contact of a positive electrode and a negative electrode, rather than due to presence of an electrically conductive foreign substance between the positive electrode and the negative electrode.

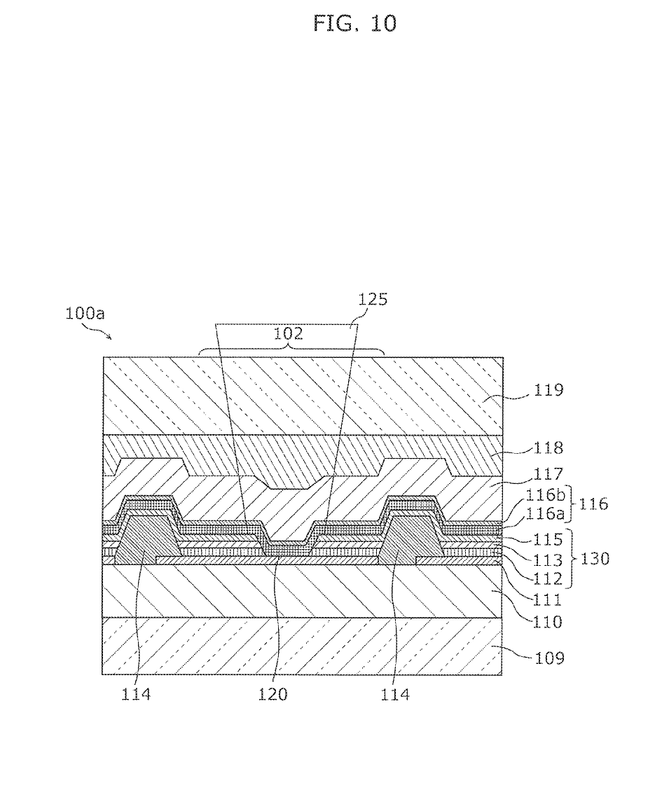

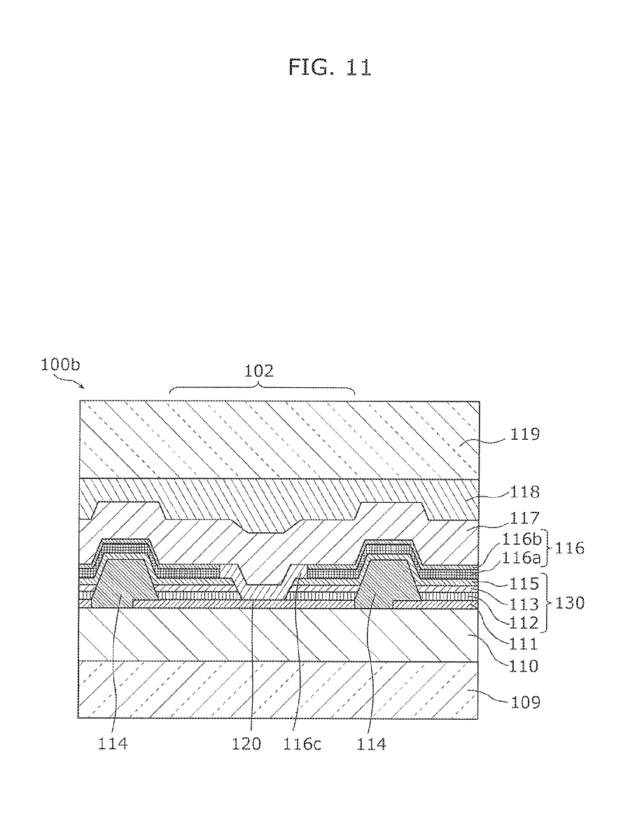

FIG. 10 is a cross-sectional schematic view illustrating a process of resolving a short circuit in the organic EL element according to the present embodiment. FIG. 11 is a cross-sectional schematic view of the organic EL element according to the present embodiment. To be more specific, FIG. 10 is a cross-sectional schematic view of an organic EL element 100a to which laser light 125 is emitted to repair the organic EL element 100a. FIG. 11 is a cross-sectional schematic view of the repaired organic EL element 100b.

As illustrated in FIG. 10, the organic EL element 100a, as with the organic EL element 1a described in Embodiment 1, includes, on a transparent glass 109, a planarizing film 110, a positive electrode 111, a hole-injection layer 112, a light-emitting layer 113, partitions 114, an electron-injection layer 115, a negative electrode 116, a thin-film sealing layer 117, a sealing resin layer 118, and a transparent glass 119.

The negative electrode 16 has a structure in which, for example, an ITO layer 116a, which is a transparent metal oxide, and a metal layer 116b are layered. Note that the ITO layer 116a may include a material such as Mg, Ag, as a transparent electrode. The metal layer 116b may be silver alloy APC.

The ITO layer 116a has a thickness of, by way of example, 30 nm or more and 90 nm or less. The metal layer 116b has a thickness of, by way of example, 15 nm or more and 30 nm or less.

Note that specific description of the configurations same as Embodiment 1 is omitted. As with Embodiment 1, in the present embodiment also, a combination of the hole-injection layer 112, the light-emitting layer 113, and the electron-injection layer 115 is referred to as an organic layer 130. If the organic EL element 1a includes a hole-transport layer and an electron-transport layer, these layers are also included in the organic layer 130. Moreover, a combination of the planarizing film 110, the positive electrode 111, the organic layer 130, the negative electrode 116, the thin-film sealing layer 117, the sealing resin layer 118, and the transparent glass 119, which are disposed in each of light-emitting region separated by the partitions 114, is referred to as a pixel 102. Moreover, in the case of manufacturing an organic EL element 100 in which color filters are disposed, the color filters are previously formed on a major surface of the transparent glass 119. Then, the transparent glass 119 is disposed on the sealing resin layer 118 applied on the thin-film sealing layer 117, with a surface down, the surface having the color filters formed thereon. Note that a combination of the thin-film sealing layer 117, the sealing resin layer 118, and the transparent glass 119 corresponds to the protective film according to the present invention.

As illustrated in FIG. 10, in the organic EL element 100a, the positive electrode 111 and the ITO layer 116a of the negative electrode 116 are in direct contact with each other at a short-circuited portion 120. Otherwise, the organic layer 130 is formed so as to be thinner in the short-circuited portion 120 than in a portion other than the short-circuited portion 120. This is due to the fact that, for example, a pinhole is formed at the short-circuited portion 120 during the process of forming the organic layer 130, after which a material from which the ITO layer 116a is formed flows in the pinhole during the process of forming the ITO layer 116a and thus the ITO layer 116a is made directly in contact with the positive electrode 111, as illustrated in the figure. The organic EL element 100a has a configuration in which a portion 116c of the negative electrode has been brought into a high-resistance state and thus the short circuit between the positive electrode 111 and the ITO layer 116a has been resolved.

Next, a process of resolving a short circuit in the short-circuited portion 120 is described, the short-circuited portion 120 being where the positive electrode 111 and the ITO layer 116a set forth above are short-circuited.

The short-circuited portion 120 is repaired by emitting the laser light 125 to the negative electrode 116 in a region proximate the short-circuited portion 120, as with Embodiment 1. Specifically, the laser light 125 is emitted, from the transparent glass 119 side, to the ITO layer 116a and the metal layer 116b in the region proximate the short-circuited portion 120 in a pixel 102 which has the short-circuited portion 120 as illustrated in FIG. 10. This granulates the structure of a portion of the ITO layer 116a and a portion of the metal layer 116b.

In the granulated portion 116c of the negative electrode, the ITO layer 116a having the granulated structure and the metal comprising the metal layer 116b are mixed and air gaps are created between the particles. Thus, it is contemplated that due to the air gaps, the granulated portion 116c of the negative electrode is less likely to pass current therethrough and has a resistance state higher than a portion of the negative electrode 116 that is not granulated.

As such, a portion of the negative electrode 116 is brought into a high-resistance state, and thereby the short circuit between the positive electrode 111 and the negative electrode 116 is resolved and light emission of the pixel 102 is recovered.

Here, the type of the laser light 125 is, for example, femtosecond laser light whose output energy is 1 μJ or greater and 30 μJ or less and pulse width is a few hundred femtoseconds. The laser light has a wavelength of, by way of example, 900 nm or more and 2500 nm or less.

Moreover, thermal energy of the laser light emitted to an area may spread to a predetermined area around the area in the organic EL element 100b. For example, the negative electrode 116 in the predetermined area may be granulated and brought into a high-resistance state. In this case also, the short circuit between the positive electrode 111 and the negative electrode 116 is resolved, recovering light emission of the pixel 102.

Moreover, a process of detecting the short-circuited portion 120 may be provided prior to the process of repairing the short-circuited portion 120.

### Other Embodiments

Other embodiments according to the present invention are now described. The embodiments described above are applicable, not only to the case where the positive electrode 11 and the negative electrode 16 are fully conducted electrically, but also to the case where, although the positive electrode 11 and the negative electrode 16 are not fully conducted electrically, a portion where the resistances of the positive electrode 11 and the negative electrode 16 are small as compared to other portions.

For example, Embodiment 1 may be applicable to the case where the size of the foreign substance 20 is smaller than the distance between the positive electrode 11 and the negative electrode 16, and, although the foreign substance 20 is not electrically conducted with the positive electrode 11 and the negative electrode 16, a distance between the foreign substance 20 and the positive electrode 11 and a distance between the foreign substance 20 and the negative electrode 16 are short and thus the positive electrode 11 or the negative electrode 16 is prone to passing current therethrough.

As such, even the short circuit between the positive electrode 11 and the negative electrode 16 that is due to the fact that the positive electrode 11 and the negative electrode 16, although they are not fully conducted electrically, have small resistances can be resolved. In other words, as with Embodiment 1, laser light 125 is emitted from the transparent glass 19 side to the negative electrode 16 that is located above the portion of the positive electrode 11 prone to passing current therethrough, to granulate the structure of a portion of the negative electrode 16 and bring the portion of the negative electrode 16 into a high-resistance state, thereby preventing a short circuit between the positive electrode 11 and the negative electrode 16.

Moreover, for example, as illustrated in Embodiment 3, the repair process described above is applicable to the case where a pinhole is formed during the process of forming the light-emitting layer 113 to form the organic layer 130, and then a material from which the negative electrode 116 is formed flows in the pinhole during the process of forming the negative electrode 116. The repair process described above is applicable also to the case where although the positive electrode 111 and the negative electrode 116 are not fully conducted electrically, they have low resistances and thus prone to passing current therethrough due to a short distance between the positive electrode 111 and the negative electrode 116.

As such, even though the positive electrode 111 and the negative electrode 116 are not fully conducted electrically, the structure of the portion 116c of the negative electrode 116 can be granulated by emitting the laser light 125 to the negative electrode 116 above the short-circuited portion from the transparent glass 119 side, as with Embodiment 3. This brings the portion of the negative electrode 116 into a high-resistance state, thereby preventing a short circuit between the positive electrode 111 and the negative electrode 116.

Note that the present invention is not limited to the embodiments described above, and various other modifications and variations can be devised without departing from the scope of the present invention.

For example, the embodiments described above have the configuration in which the lower electrode is the positive electrode and the upper electrode is the negative electrode. However, the lower electrode may be the negative electrode and the upper electrode may be the positive electrode. Moreover, the configurations of the components of the organic EL element, which are the planarizing film, positive electrode, hole-injection layer, light-emitting layer, partitions, electron-Injection layer, negative electrode, thin-film sealing layer, sealing resin layer, and transparent glass are not limited to the configurations illustrated in the above embodiments. The materials, configurations, and the ways of forming the components may be modified. For example, a hole-transport layer may be disposed between the hole-injection layer and the light-emitting layer or an electron-transport layer may be disposed between the electron-injection layer and the light-emitting layer. Moreover, the color filters for adjusting colors red, green, and blue may be disposed on the bottom surface of the transparent glass so as to cover the light-emitting regions separated by the partitions.

Moreover, the irradiation position of the laser light is not limited to the above embodiments, and may be set to a predetermined area where a foreign substance or short-circuited portion is included, or may be set to a foreign substance or short-circuited portion only. Moreover, the irradiation position of the laser light may be a region surrounding a foreign substance or short-circuited portion. Moreover, not limiting to the negative electrode, the laser light may be emitted to the positive electrode as well.

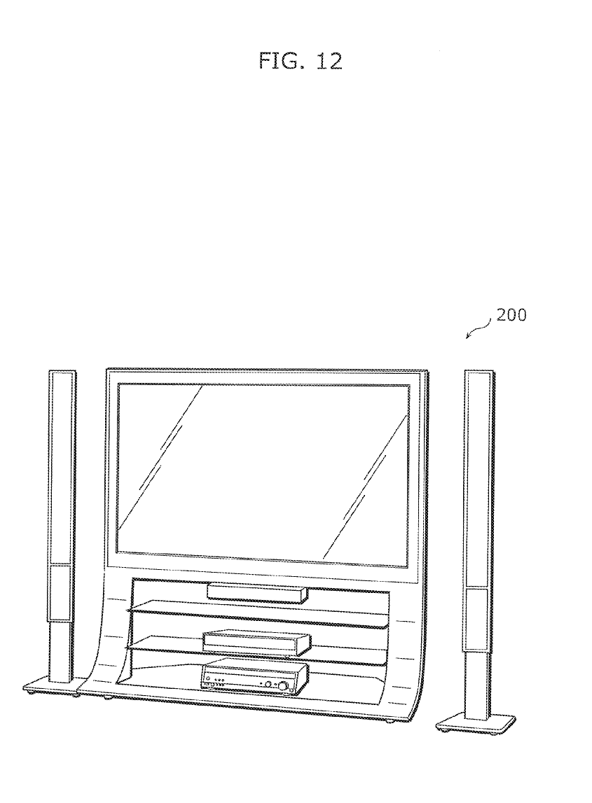

Moreover, various modifications to the embodiments that may be conceived by a person skilled in the art or combinations of the components of different embodiments are intended to be included within the scope of the present invention, without departing from the spirit of the present invention. For example, a thin, flat-screen television system 200 which includes the organic EL element according to the present invention as illustrated in FIG. 12 is also included in the present invention.

### INDUSTRIAL APPLICABILITY

A method for manufacturing an organic EL element and the organic EL element according to the present invention are useful, in particular, in technical fields where large screens and high resolutions are demanded, such as flat-screen televisions and displays of personal computers, etc.

### REFERENCE SIGNS LIST

1a, 1b, 50a, 50b, 100a, 100b organic electro-luminescent element
2, 102 pixel
11, 111 positive electrode (lower electrode)
12, 112 hole-injection layer (organic layer)
13, 113 light-emitting layer (organic layer)
15, 115 electron-injection layer (organic layer)
16, 116 negative electrode (upper electrode)
16a, 116a ITO layer (transparent electrically conductive material layer)
16b, 116b metal layer
16c, 16d, 116c portion of negative electrode
20 foreign substance
25, 125 laser light
30, 130 organic layer
120 short-circuited portion
200 thin, flat-screen television system

1. A method for manufacturing an organic electro-luminescent (EL) element, the method comprising:
a first process of preparing an organic EL element which includes a lower electrode, an organic layer which includes a light-emitting layer, and an upper electrode, at least one of the lower electrode and the upper electrode including a transparent electrically conductive material layer and a metal layer having an index of refraction higher than the transparent electrically conductive material layer, the organic EL element having a short-circuited portion where the lower electrode and the upper electrode are short-circuited; and
a second process of emitting femtosecond laser light to at least one of: the transparent electrically conductive material layer and the metal layer in the short circuited portion where the lower electrode and the upper electrode are short-circuited; and the transparent electrically conductive material layer and the metal layer around the short-circuited portion, to change a structure of the transparent electrically conductive material layer and a structure of the metal layer and bring the transparent electrically conductive material layer and the metal layer into high-resistance states.

2. The method according to claim 1, wherein
the metal layer includes silver.

3. The method according to claim 1, wherein
the metal layer includes magnesium.

4. The method according to claim 1, wherein
the transparent electrically conductive material layer includes a transparent metal oxide.

5. The method according to claim 1, wherein
the organic layer in the short-circuited portion contains an electrically conductive foreign substance.

6. The method according to claim 5, further comprising
detecting the electrically conductive foreign substance, wherein
the femtosecond laser light is emitted to the transparent electrically conductive material layer and the metal layer in a region around the electrically conductive foreign substance.

7. The method according to claim 1, wherein
the organic layer is thinner in the short-circuited portion than in portions other than the short-circuited portion.

8. An organic EL element comprising: a lower electrode; an organic layer which includes a light-emitting layer; and an upper electrode, wherein
at least one of the lower electrode and the upper electrode includes a transparent electrically conductive material layer and a metal layer having an index of refraction higher than the transparent electrically conductive material layer, and
a portion of the transparent electrically conductive material layer and a portion of the metal layer have been changed in structure by laser radiation and are in high-resistance states.

9. The organic EL element according to claim 8, wherein
the metal layer includes silver.

10. The organic EL element according to claim 8, wherein
the metal layer includes magnesium.

11. The organic EL element according to claim 8, wherein
an electrically conductive foreign substance is present proximate the portion of the transparent electrically conductive material layer and the portion of the metal layer.
